(19) United States
(12) Patent Application Publication
(10) Pub. No.: US 2020/0168430 A1
(43) Pub. Date: May 28, 2020

(54) ELECTRON BEAM IMAGE ACQUISITION APPARATUS AND ELECTRON BEAM IMAGE ACQUISITION METHOD

(71) Applicant: NuFlare Technology, Inc., Yokohama-shi (JP)

(72) Inventors: Kazuhiko INOUE, Yokohama-shi (JP); Atsushi ANDO, Edogawa-ku (JP)

(73) Assignee: NuFlare Technology, Inc., Yokohama-shi (JP)

(21) Appl. No.: 16/668,268

(22) Filed: Oct. 30, 2019

(30) Foreign Application Priority Data
Nov. 28, 2018 (JP) 2018-222443

(51) Int. Cl. H01J 37/12; H01J 37/244; H01J 37/20; H01J 37/145; H01J 37/141

(52) U.S. Cl. CPC H01J 37/12; H01J 37/244; H01J 2237/2448; H01J 37/145; H01J 37/141; H01J 37/20

(57) ABSTRACT

According to one aspect of the present invention, an electron beam image acquisition apparatus includes a first electrostatic lens group correcting a shift amount of a focus position of the primary electron beam from the reference position on the surface of the substrate occurring according to movement of the stage, and a plurality of variation amounts of the primary electron beam on the surface of the substrate by correcting the shift amount of the focus position of the primary electron beam; and a second electrostatic lens group correcting a plurality of variation amounts of an image of a secondary electron beam being emitted from the substrate by irradiating the substrate with the primary electron beam corrected by the first electrostatic lens group, the secondary electron beam passing through at least one electrostatic lens of the first electrostatic lens group.

### CROSS-REFERENCE TO RELATED APPLICATION

This application is based upon and claims the benefit of priority from prior Japanese Patent Application No. 2018-222443 filed on Nov. 28, 2018 in Japan, the entire contents of which are incorporated herein by reference.

### BACKGROUND OF THE INVENTION

### Field of the Invention

Embodiments relate to a multiple electron beam image acquisition apparatus and a multiple electron beam image acquisition method. For example, embodiments relate to an apparatus for acquiring a secondary electron image of a pattern emitted by irradiation of a multiple beam with an electron beam.

### Related Art

In recent years, with the high integration and large capacity of large scale integrated circuits (LSIs), the line width of a circuit required for a semiconductor element has become narrower and narrower. In addition, it is essential to improve the yield for the manufacture of LSIs which requires a lot of manufacturing cost. However, as represented by 1-gigabit class random access memory (DRAM), the pattern constituting the LSI is in the order of sub-micrometer to nanometer. In recent years, with the miniaturization of the dimensions of LSI patterns formed on semiconductor wafers, the dimensions to be detected as pattern defects have become extremely small. Therefore, there is a need to improve the accuracy of a pattern inspection apparatus that inspects defects of an ultrafine pattern transferred onto the semiconductor wafer. In addition, as one of the major factors for lowering the yield, there is a pattern defect of a mask used at the time of exposing and transferring an ultrafine pattern on a semiconductor wafer by photolithography. For this reason, there is a need to improve the accuracy of a pattern inspection apparatus that inspects defects of a transfer mask used in LSI manufacturing.

As an inspection method, there has been known a method of performing inspection by comparing a measurement image obtained by imaging a pattern formed on a substrate such as a semiconductor wafer or a lithography mask with a design data or a measurement image obtained by imaging the same pattern on the substrate. For example, as a pattern inspection method, there are “die to die (die-die) inspection” of comparing measurement image data obtained by imaging the same pattern at different positions on the same substrate and “die to database (die-database) inspection” of generating a design image data (reference image) on the basis of a design data with a pattern designed and comparing the design image data with a measurement image which is a measurement data obtained by imaging the pattern. The captured image is transmitted to the comparison circuit as measurement data. After alignment of the images, the comparison circuit compares the measurement data and the reference data according to an appropriate algorithm, and in a case where the data do not match, it is determined that there is a pattern defect.

With respect to the pattern inspection apparatus described above, in addition to an apparatus for irradiating an inspection target substrate with a laser beam and capturing a transmission image or a reflection image, development of an inspection apparatus for acquiring a pattern image by scanning an inspection target substrate with an electron beam and detecting secondary electrons emitted from the inspection target substrate caused by the irradiation of the electron beam is also in progress. With respect to an inspection apparatus using an electron beam, development of an apparatus using multiple beams is also in progress. Herein, the height position of the surface of the substrate is varied due to the unevenness such as the dispersion of the thickness of the inspection target substrate. In a case where the substrate is irradiated with the multiple beams while the stage is continuously moved, in order to obtain a high resolution image, it is necessary to keep aligning the focus position of the multiple beams on the surface of the substrate. With respect to the substrate on the stage that is continuously moved, since it is difficult for the objective lens to cope with the unevenness of the surface of the substrate, it is necessary to dynamically correct the substrate by using an electrostatic lens having high responsiveness. If the focus position is corrected by using an electrostatic lens, the magnification variation and the rotation variation of the image on the surface of the substrate also occur accordingly, so that it is necessary to simultaneously correct these three variation factors of the focus position and the magnification variation and rotation variation of the image. For example, three electrostatic lenses are used to correct these variation factors (refer to, for example, JP-A-2014-127568). However, secondary electrons emitted from the inspection target substrate are influenced by the positive electric field of any one of the electrostatic lenses, and the focus position variation, the magnification variation, and the rotation variation newly occur on the detection surface of the detector. For this reason, there is a problem that an error occurs in the detection of the secondary electrons in the detector. Such a problem is not limited to the inspection apparatus and may similarly occur in an apparatus which focuses multiple beams on a continuously moving substrate to acquire an image.

### BRIEF SUMMARY OF THE INVENTION

According to one aspect of the present invention, an electron beam image acquisition apparatus includes:

a stage on which a substrate to be irradiated with a primary electron beam being capable to be placed;

an objective lens focusing the primary electron beam on a reference position of a surface of the substrate;

a first electrostatic lens group including a plurality of electrostatic lenses, one electrostatic lens of the first electrostatic lens group being arranged in a magnetic field of the objective lens, the first electrostatic lens group correcting a shift amount of a focus position of the primary electron beam from the reference position on the surface of the substrate occurring according to movement of the stage, and a plurality of variation amounts of the primary electron beam on the surface of the substrate by correcting the shift amount of the focus position of the primary electron beam;

a second electrostatic lens group, arranged at a position with the primary electron beam not passing through the position and including a plurality of electrostatic lenses, correcting a plurality of variation amounts of an image of a secondary electron beam being emitted from the substrate by irradiating the substrate with the primary electron beam corrected by the first electrostatic lens group, the secondary electron beam passing through at least one electrostatic lens of the first electrostatic lens group; and

a detector detecting the secondary electron beam corrected by the second electrostatic lens group.

According to another aspect of the present invention, an electron beam image acquisition method includes:

irradiating a substrate with a primary electron beam while moving a stage with the substrate being mounted, in a state of a focus position of the primary electron beam being aligned with a reference position of a surface of the substrate by an objective lens;

correcting a shift amount of the focus position of the primary electron beam from the reference position of the surface of the substrate occurring according to movement of the stage and a variation amount of the primary electron beam on the surface of the substrate by correcting the shift amount of the focus position of the primary electron beam by a first electrostatic lens group, one electrostatic lens of the first electrostatic lens group being arranged in a magnetic field of the objective lens;

correcting a variation amount of an image of a secondary electron beam being emitted from the substrate caused by irradiating the substrate with a primary electron beam corrected by the first electrostatic lens group, the secondary electron beam passing through at least one electrostatic lens of the first electrostatic lens group, by a second electrostatic lens group arranged at a position with the primary electron beam not passing through the position and configured with a plurality of electrostatic lenses; and

detecting the secondary electron beam corrected by the second electrostatic lens group and acquiring a secondary electron image on the basis of a signal of the detected secondary electron beam.

### BRIEF DESCRIPTION OF THE DRAWINGS

FIG. 1 is a configuration diagram illustrating a configuration of a pattern inspection apparatus according to Embodiment 1;

FIG. 2 is a conceptual diagram illustrating a configuration of a shaping aperture array substrate in Embodiment 1;

FIG. 3A and FIG. 3B are diagrams illustrating an example of an arrangement configuration of electromagnetic lenses and electrostatic lenses and a central beam trajectory according to Embodiment 1;

FIG. 4 is a diagram illustrating a relationship between a shift amount of a focus position of multiple primary electron beams and a magnification variation amount and a rotation variation amount of an image and a shift amount of a focus position of multiple secondary electron beams and a magnification variation amount and a rotation variation amount of an image in Embodiment 1;

FIG. 5 is a flowchart illustrating main steps of an inspection method according to Embodiment 1;

FIG. 6 is a diagram illustrating an example of a correlation table in Embodiment 1;

FIG. 7 is a diagram illustrating an example of a plurality of chip regions formed on the semiconductor substrate in Embodiment 1;

FIG. 8 is a diagram illustrating a multiple beam scan operation in Embodiment 1;

FIGS. 9A to 9D are diagrams illustrating a variation of multiple secondary electron beams on a detection surface of a detector and a corrected state in Embodiment 1; and

FIG. 10 is a configuration diagram illustrating an example of a configuration in a comparison circuit in Embodiment 1.

### DETAILED DESCRIPTION OF THE INVENTION

Hereinafter, in an embodiment, an apparatus and method capable of detecting secondary electrons with high accuracy in an apparatus for acquiring an image by focusing multiple beams on a continuously moving substrate will be described.

In addition, hereinafter, a multiple electron beam inspection apparatus will be described as an example of the multiple electron beam irradiation apparatus in the embodiment. However, the multiple electron beam irradiation apparatus is not limited to the inspection apparatus and may be an apparatus that irradiates the multiple electron beam by using, for example, electron optics.

### Embodiment 1

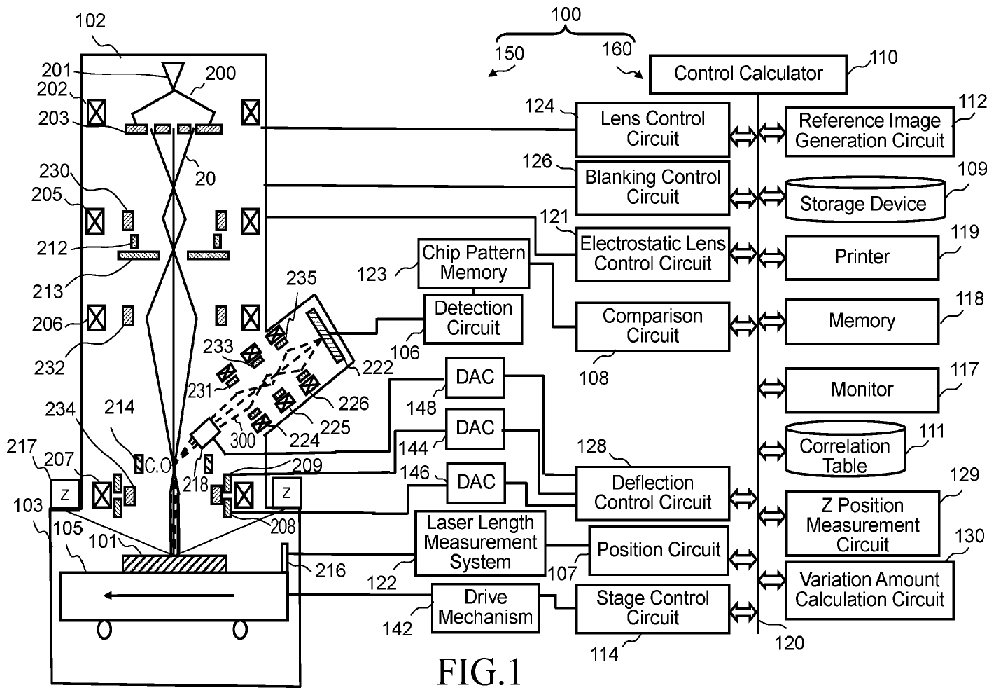

FIG. 1 is a configuration diagram illustrating a configuration of a pattern inspection apparatus according to Embodiment 1. In FIG. 1, an inspection apparatus 100 for inspecting a pattern formed on a substrate is an example of the multiple electron beam inspection apparatus. The inspection apparatus 100 includes an image acquisition mechanism 150 and a control system 160. The image acquisition mechanism 150 includes an electron beam column 102 (electron optical column) and an inspection chamber 103. In the electron beam column 102, an electron gun assembly 201, an electromagnetic lens 202, a shaping aperture array substrate 203, an electromagnetic lens 205, an electrostatic lens 230, a collective blanking deflector 212, a limiting aperture substrate 213, an electromagnetic lens 206, an electrostatic lens 232, an electromagnetic lens 207 (objective lens), a main deflector 208, a sub deflector 209, an electrostatic lens 234, a beam separator 214, a deflector 218, an electromagnetic lens 224, an electrostatic lens 231, an electromagnetic lens 225, an electrostatic lens 233, an electromagnetic lens 226, an electrostatic lens 235, and a multiple detector 222 are arranged.

In the inspection chamber 103, a stage 105 that is movable at least in the XYZ directions is arranged. A substrate 101 (target object) to be inspected is arranged on the stage 105. The substrate 101 includes a mask substrate for exposure and a semiconductor substrate such as a silicon wafer.

In a case where the substrate 101 is the semiconductor substrate, a plurality of chip patterns (wafer dies) are formed on the semiconductor substrate. In a case where the substrate 101 is the mask substrate for exposure, chip patterns are formed on the mask substrate for exposure. The chip pattern is configured with a plurality of figures. A plurality of chip patterns (wafer dies) are formed on the semiconductor substrate by exposing and transferring the chip patterns formed on the mask substrate for exposure onto the semiconductor substrate several times. Hereinafter, a case where the substrate 101 is the semiconductor substrate will be mainly described. The substrate 101 is arranged on the stage 105, for example, with a pattern formation surface facing upward. In addition, on the stage 105, a mirror 216 for reflecting a laser beam for laser length measurement irradiated from a laser length measurement system 122 arranged outside the inspection chamber 103 is arranged. In addition, on the inspection chamber 103, a height position sensor (Z sensor) 217 for measuring the height position of the surface of the substrate 101 is arranged. The Z sensor 217 irradiates the surface of the substrate 101 with laser light obliquely from the upper side by using a light projector and measures the height position of the surface of the substrate 101 by using reflected light received by a light receiver. The multiple detector 222 is connected to a detection circuit 106 outside the electron beam column 102. The detection circuit 106 is connected to a chip pattern memory 123.

In the control system 160, a control calculator 110 for controlling the entire inspection apparatus 100 is connected to a position circuit 107, a comparison circuit 108, a reference image generation circuit 112, a stage control circuit 114, an electrostatic lens control circuit 121, a lens control circuit 124, a blanking control circuit 126, a deflection control circuit 128, a Z position measurement circuit 129, a variation amount calculation circuit 130, storage devices 109 and 111 such as magnetic disk drives, a monitor 117, a memory 118, and a printer 119 via a bus 120. In addition, the deflection control circuit 128 is connected to digital-to-analog conversion (DAC) amplifiers 144, 146, and 148. The DAC amplifier 146 is connected to the main deflector 208, and the DAC amplifier 144 is connected to the sub deflector 209. The DAC amplifier 148 is connected to the deflector 218.

In addition, the chip pattern memory 123 is connected to the comparison circuit 108. In addition, the stage 105 is driven by a drive mechanism 142 under the control of the stage control circuit 114. In the drive mechanism 142, for example, a drive system such as a 3-axis (X-Y-θ) motor which drives in the X direction, Y direction, and θ direction in the stage coordinate system is configured, and thus, the stage 105 can be moved in the X, Y, and θ directions. As these X motor, Y motor, and θ motor (not illustrated), for example, step motors can be used. The stage 105 can be moved in the horizontal direction and the rotational direction by motors of the axes of X, Y, and θ. In addition, the stage 105 can be moved in the Z direction (height direction) by using, for example, a piezo element or the like. Then, the movement position of the stage 105 is measured by the laser length measurement system 122 and supplied to the position circuit 107. The laser length measurement system 122 measures the position of the stage 105 by the principle of laser interferometry by receiving the reflected light from the mirror 216. In the stage coordinate system, an X direction, a Y direction, and a θ direction are set with respect to a plane perpendicular to the optical axis of, for example, the multiple primary electron beams.

The electromagnetic lens 202, the electromagnetic lens 205, the electromagnetic lens 206, the electromagnetic lens 207 (objective lens), the electromagnetic lens 224, the electromagnetic lens 225, the electromagnetic lens 226, and the beam separator 214 are controlled by the lens control circuit 124. In addition, the collective blanking deflector 212 is configured with electrodes having two or more poles and is controlled by the blanking control circuit 126 through a DAC amplifier (not illustrated) for each electrode. Each electrostatic lens 230, 231, 232, 233, 234, and 235 is configured with, for example, three or more stages of electrode substrates of which central portion is opened, and the middle stage electrode substrate is controlled by the electrostatic lens control circuit 121 through a DAC amplifier (not illustrated). A ground potential is applied to the upper and lower electrode substrates of the electrostatic lenses 230, 231, 232, 233, 234, and 235. The sub deflector 209 is configured with electrodes having four or more poles and is controlled by the deflection control circuit 128 through the DAC amplifier 144 for each electrode. The main deflector 208 is configured with electrodes having four or more poles and is controlled by the deflection control circuit 128 through the DAC amplifier 146 for each electrode. The deflector 218 is configured with electrodes having four or more poles and is controlled by the deflection control circuit 128 through the DAC amplifier 148 for each electrode.

An electrostatic lens group (first electrostatic lens group) configured with three electrostatic lenses 230, 232, and 234 is arranged in primary electron optics (irradiation optics). The electrostatic lens 230 is arranged in the magnetic field of the electromagnetic lens 205. The electrostatic lens 232 is arranged in the magnetic field of the electromagnetic lens 206. The electrostatic lens 234 is arranged in the magnetic field of the electromagnetic lens 207 (objective lens).

In this manner, one of the electrostatic lens groups in the primary electron optics is arranged in the magnetic field of the objective lens. An electrostatic lens group (second electrostatic lens group) configured with three electrostatic lenses 231, 233, and 235 is arranged in secondary electron optics (detection optics). The electrostatic lens 231 is arranged in the magnetic field of the electromagnetic lens 224. The electrostatic lens 233 is arranged in the magnetic field of the electromagnetic lens 225. The electrostatic lens 235 is arranged in the magnetic field of the electromagnetic lens 226. For example, in each electrostatic lens, the middle stage electrode substrate of the three stages of electrode substrates is arranged at the magnetic field center height position (or main lens surface) of the corresponding electromagnetic lens.

As a result, since the trajectory of the electron beam is corrected by the electrostatic lens in a state where the moving speed of the electrons is lowered by the lens function of the electromagnetic lens, in other words, in a state where the energy of the electrons is reduced, it is possible to reduce the potential applied to the middle stage electrode substrate serving as the control electrode.

A high voltage power supply circuit (not illustrated) is connected to the electron gun assembly 201, and along with the application of an acceleration voltage from the high voltage power supply circuit between a filament (cathode) (not illustrated) and an extraction electrode (anode) in the electron gun assembly 201, by the application of a voltage of another extraction electrode (Wehnelt) and the heating of the cathode at a predetermined temperature, a group of the electrons emitted from the cathode is accelerated to be emitted as the electron beam 200.

Herein, FIG. 1 illustrate a configuration necessary to describe Embodiment 1. The inspection apparatus 100 may generally have other necessary configurations.

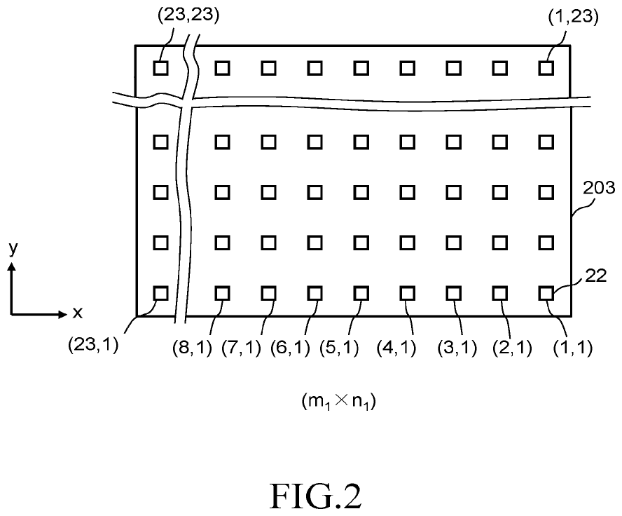

FIG. 2 is a conceptual diagram illustrating a configuration of a shaping aperture array substrate in Embodiment 1. In FIG. 2, in the shaping aperture array substrate 203, holes (openings) 22 of a two-dimensional shape of width (x direction) m₁ columns x length (y direction.) n₁ stages (m₁ and n₁ are integers of 2 or more) are formed in the x and y directions at a predetermined arrangement pitch. In the example of FIG. 2, a case where the 23×23 holes (openings) 22 are formed is illustrated. The holes 22 are formed with rectangles having the same size and shape. Alternatively, the holes may be circles having the same outer diameter. A portion of the electron beam 200 passes through the plurality of holes 22 to form the multiple beams 20. Herein, the example where the holes 22 having two or more columns in both the width and length directions (x and y directions) are arranged is illustrated, but embodiments are not limited thereto. For example, a plurality of columns may be arranged in one of the width and length directions (x and y directions), and one column may be arranged in the other direction. In addition, the arrangement method of the holes 22 is not limited to a case where the holes are arranged in a grid shape in the width and length directions as illustrated in FIG. 2. For example, the holes of the k-th column and the holes of the (k+1)-th column in the length direction (y direction) may be arranged to be shifted by a dimension “a” in the width direction (x direction). Similarly, the holes of the (k+1)-th column and the holes of the (k+2)-th column in the length direction (y direction) may be arranged to be shifted by a dimension “b” in the width direction (x direction).

Next, operations of the image acquisition mechanism 150 in the inspection apparatus 100 will be described.

The electron beam 200 emitted from the electron gun assembly 201 (emission source) is refracted by the electromagnetic lens 202, the entire shaping aperture array substrate 203 is illuminated with the electron beam 200. As illustrated in FIG. 2, a plurality of holes 22 (openings) are formed in the shaping aperture array substrate 203, and the area including all the plurality of holes 22 is illuminated with the electron beam 200. The respective portions of the electron beam 200 with which the positions of the plurality of holes 22 are irradiated pass through the plurality of holes 22 of the shaping aperture array substrate 203 to form the multiple primary electron beams 20.

The formed multiple primary electron beams 20 are refracted by the electromagnetic lens 205 and the electromagnetic lens 206, and while repeating the intermediate image and the crossover, the multiple primary electron beams pass through the beam separator 214 arranged at the crossover position of each beam of the multiple primary electron beams 20 and travel to the electromagnetic lens 207 (objective lens). Then, the electromagnetic lens 207 focuses the multiple primary electron beams 20 on the substrate 101. The multiple primary electron beams 20 focused on the surface of the substrate 101 (target object) by the objective lens 207 are collectively deflected by the main deflector 208 and the sub deflector 209, and thus, each irradiation position of each beam on the substrate 101 is irradiated with the multiple primary electron beams. In addition, in a case where the entire multiple primary electron beams 20 are collectively deflected by the collective blanking deflector 212, the position is shifted from the hole at the center of the limiting aperture substrate 213 and is shielded by the limiting aperture substrate 213. On the other hand, the multiple primary electron beams 20 not deflected by the collective blanking deflector 212 pass through the hole in the center of the limiting aperture substrate 213 as illustrated in FIG. 1. By turning on/off the collective blanking deflector 212, blanking control is performed, so that on/off of the beam is collectively controlled. Therefore, the limiting aperture substrate 213 shields the multiple primary electron beams 20 deflected so as to be in the beam OFF state by the collective blanking deflector 212. The multiple primary electron beams 20 for inspection (for image acquisition) is formed by the beam group that is formed from the time of the beam ON to the time of the beam OFF and passes through the limiting aperture substrate 213.

If a desired position of the substrate 101 is irradiated with the multiple primary electron beams 20, due to the irradiation with the multiple primary electron beams 20, a bundle of secondary electrons (multiple secondary electron beams 300) including reflected electrons is emitted corresponding to each beam of the multiple primary electron beams 20 (multiple primary electron beams) from the substrate 101.

The multiple secondary electron beams 300 emitted from the substrate 101 travel through the electromagnetic lens 207 and the electrostatic lens 234 to the beam separator 214.

Herein, the beam separator 2140 generates an electric field and a magnetic field in a direction perpendicular to each other on the surface perpendicular to the direction (central axis of the trajectory) along which the central beam of the multiple primary electron beams 20 travels. The electric field exerts a force in the same direction regardless of the direction of travel of the electrons. In contrast, the magnetic field exerts a force according to Fleming's left hand law. For this reason, the direction of the force exerted on the electrons can be changed by the penetration direction of the electrons. With respect to the multiple primary electron beams 20 penetrating into the beam separator 214 from the upper side, the force by the electric field and the force by the magnetic field cancel each other, and thus, the multiple primary electron beams 20 travel straight downward. On the other hand, with respect to the multiple secondary electron beams 300 penetrating into the beam separator 214 from the lower side, both the force by the electric field and the force by the magnetic field are exerted in the same direction, and thus, the multiple secondary electron beams 300 are bent obliquely upward to be separated from the multiple primary electron beams 20.

The multiple secondary electron beams 300 which is bent obliquely upward to be separated from the multiple primary electron beams 20 are further bent by the deflector 218 and refracted by the electromagnetic lenses 224, 225, and 226 to be projected onto the multiple detector 222. The multiple detector 222 detects the projected multiple secondary electron beams 300. The multiple detector 222 has, for example, a diode-type two-dimensional sensor (not illustrated). Then, at the position of the diode-type two-dimensional sensor corresponding to each beam of the multiple primary electron beams 20, each secondary electron of the multiple secondary electron beams 300 collides with the diode-type two-dimensional sensor to generate electrons, and thus, a secondary electron image data is generated for each pixel. The intensity signal detected by the multiple detector 222 is output to the detection circuit 106.

Herein, the substrate 101 to be inspected has unevenness due to the variation in thickness, and thus, the height position of the surface of the substrate 101 is changed due to the unevenness. If the height position of the surface of the substrate 101 is varied, the focus position is shifted, so that the size of each beam with which the substrate 101 is irradiated is changed. If the beam size is changed, the number of secondary electrons emitted from the irradiation position is changed, which causes an error in the detected intensity, and thus, the obtained image is changed. Therefore, in a case where the substrate 101 is irradiated with the multiple primary electron beams 20 while the stage 105 is continuously moved, in order to obtain a high resolution image, it is necessary to keep aligning the focus position of the multiple primary electron beams 20 on the surface of the substrate 101. With respect to the substrate 101 on the stage 105 that is continuously moved, since it is difficult for the electromagnetic lens 207 (objective lens) to cope with the unevenness of the surface of the substrate 101, it is necessary to dynamically correct the substrate by using, for example, the electrostatic lens having high responsiveness.

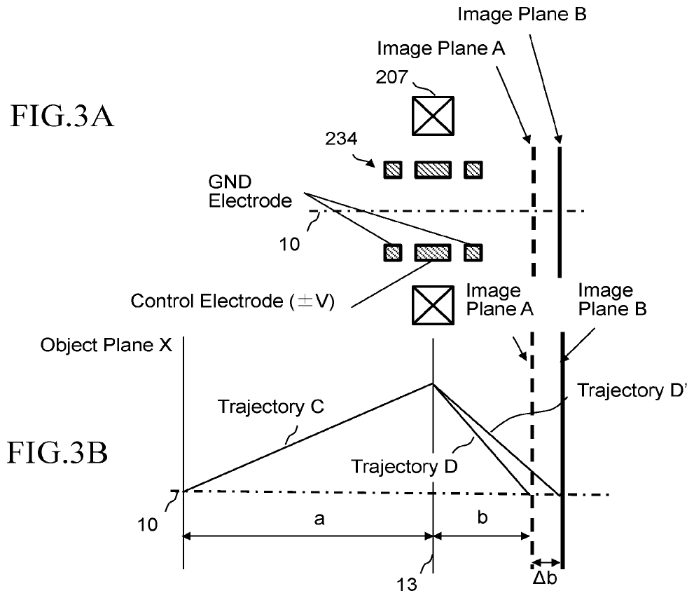

FIG. 3A and FIG. 3B are diagrams illustrating an example of an arrangement configuration of the electromagnetic lenses and the electrostatic lenses and a central beam trajectory in Embodiment 1. In FIG. 3A, the electrostatic lens 234 is configured with three stages of electrode substrates. Then, the middle stage electrode substrate serving as the control electrode is arranged at the magnetic field center position of the electromagnetic lens 207, and the ground potential is applied to the upper stage electrode substrate and the lower stage electrode substrate. First, the lens adjustment is performed to adjust each of the electromagnetic lenses 205, 206, and 207 so that the beam is focused on the surface of the substrate 101. In such a case, in the example of FIG. 3B, the central beam of the multiple primary electron beams 20 is incident on the electromagnetic lens 207 while spreading as illustrated by a trajectory C with respect to the trajectory center axis 10 of the multiple primary electron beams 20. Then, the beam is refracted at the main surface 13 of the lens by the electromagnetic lens 207 and is focused as illustrated by the trajectory D to form an image on an image plane A. The other beams of the multiple primary electron beams 20 similarly spread and are incident on the electromagnetic lens 207. Then, the beam is refracted at the main surface 13 of the lens by the electromagnetic lens 207 and focused to form an image on the image plane A. Herein, in a case where the surface of the substrate 101 variates, an electrostatic field is generated by the electrostatic lens 234 to change the focusing function in accordance with the change of the height position of the surface of the substrate 101, and thus, the beam converges along the trajectory D′ to form an image on an image plane B. Due to the focusing function, the magnification M of the multiple primary electron beams 20 changes from b/a to (b+Δb)/a. It can be seen that the magnification of the image changes according to the variation of the image forming surface (focus position) in this manner. In addition, simultaneously, rotation variation of the multiple primary electron beams also occurs. Herein, the main surface 13 of the lens denotes the plane of the intersection point of the trajectory C of electrons emitted from an object plane X to the main surface 13 of the lens and the trajectory D of electrons traveling from the main surface 13 of the lens toward the intermediate image plane A (trajectory D′ of electrons traveling toward the intermediate image plane B). The same applies to the relationship between the electrostatic lens 230 and the electromagnetic lens 205 and the relationship between the electrostatic lens 232 and the electromagnetic lens 206. In this manner, since each electrostatic lens corrects the focus position, the magnification of the image, and the like by changing the focusing trajectory of each beam of the multiple primary electron beams 20, each beam needs to spread without forming an image. Therefore, each electrostatic lens is arranged at a position different from the image plane conjugate position of each beam.

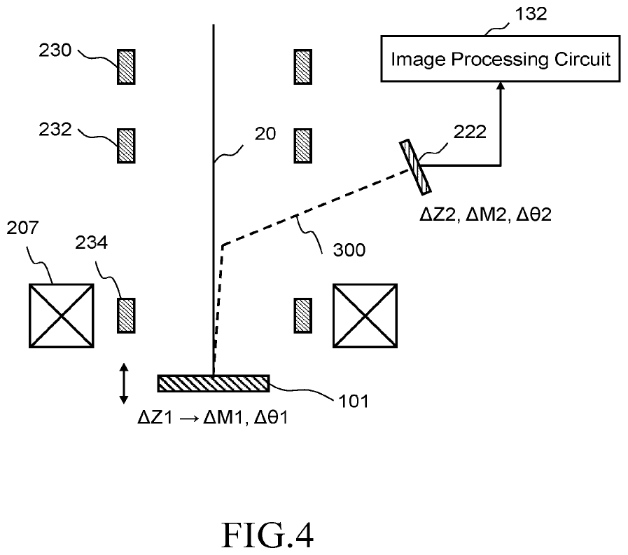

FIG. 4 is a diagram illustrating a relationship between the shift amount of the focus position of the multiple primary electron beams and the magnification variation amount and the rotation variation amount of the image and the shift amount of the focus position of the multiple secondary electron beams and the magnification variation amount and the rotation variation amount of the image in Embodiment 1. In FIG. 4, if the focus position variation (shift amount ΔZ1 of the focus position) of the multiple primary electron beams 20 caused by the variation of the height position of the surface of the substrate 101 is corrected, the magnification variation (magnification variation amount ΔM1) and the rotation variation (rotation variation amount Δθ1) of the image also occur accordingly. For this reason, it is necessary to simultaneously correct these three variation factors. Three or more electrostatic lenses are used to correct these three variation factors. In the example of FIG. 1, the three electrostatic lenses 230, 232, and 234 simultaneously correct these three variation factors. However, as described above, since the multiple secondary electron beams 300 emitted from the inspection target substrate 101 pass through the electrostatic lens 234 arranged in the magnetic field of the electromagnetic lens 207 (objective lens), the multiple secondary electron beams 300 are influenced by the positive electric field of the electrostatic lens 234. Therefore, the focus position variation (focus position variation amount ΔZ2), the magnification variation (magnification variation amount ΔM2), and the rotation variation (rotation variation amount Δθ2) of the multiple secondary electron beams 300 newly occur on the detection surface of the multiple detector 222. For this reason, an error occurs in detection of secondary electrons in the detector. Then, in Embodiment 1, the three electrostatic lenses 231, 233, and 235 are arranged in the secondary electron optics (detection optics) through which the multiple primary electron beams 20 do not pass, and the focus position variation, the magnification variation, and the rotation variation on the detection surface newly occurring in the multiple secondary electron beams 300 are corrected by the three electrostatic lenses 231, 233, and 235. In addition, the relationship between the electrostatic lens 234 and the electromagnetic lens 207 described in FIGS. 3A and 3B is similar to the relationship between the electrostatic lens 231 and the electromagnetic lens 224, the relationship between the electrostatic lens 233 and the electromagnetic lens 225, and the relationship between the electrostatic lens 235 and the electromagnetic lens 226 with respect to the multiple secondary electron beams 300. In addition, for each of the electrostatic lenses 231, 233, and 235 in the secondary electron optics, since the focus position, the magnification of the image, and the like are corrected by changing the focusing trajectory of each beam of the multiple secondary electron beams 300, it is necessary that the beam spreads without forming an image. Therefore, each electrostatic lens is arranged at a position different from the image plane conjugate position of each beam.

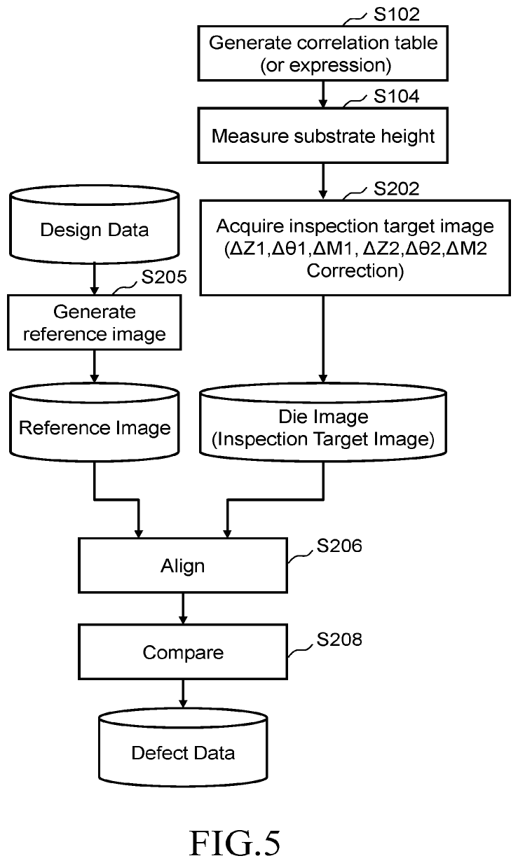

FIG. 5 is a flowchart illustrating main steps of an inspection method according to Embodiment 1. In FIG. 5, in the inspection method according to Embodiment 1, a series of steps called a correlation table (or correlation expression) generation step (S102), a substrate height measurement step (S104), an inspection target image acquisition step (S202), a reference image generation step (S205), an alignment step (S206), and a comparison step (S208) are performed.

In the correlation table (or correlation expression) generation step (S102), a correlation table (or approximation expression) is generated in which the focus position variation amount ΔZ2 of the multiple secondary electron beams 300 on the detection surface of the multiple detector 222 and the rotation variation amount Δθ2 and the magnification variation amount ΔM2 of the image occurring by correcting the shift amount ΔZ1 of the focus position of the multiple primary electron beams 20 from the reference position caused by the variation of the height position of the surface of the substrate 101 and the rotation variation amount Δθ1 and the magnification variation amount ΔM1 of the image of the multiple primary electron beams on the surface of the substrate 101 occurring by correcting the shift amount ΔZ1 of the focus position of the multiple primary electron beams 20 with the electrostatic lenses 230, 232, 234 are defined depending on the shift amount ΔZ1 of the focus position from the reference position of the substrate 101. Specifically, the generation is performed as follows. By the electromagnetic lens 207 (objective lens), the focus position of the multiple beams 20 is aligned on the sample substrate on the stage 105 which is aligned with the reference height position. From such a state, the stage 105 is variably moved in the Z direction. Each height position is measured by the Z sensor 217. Each height position moved is the shift amount ΔZ1 of the focus position of the multiple beams 20. For example, the electrostatic lens 234 is used to correct the shift amount ΔZ1 of the focus position of the multiple primary electron beams 20 on the surface of the substrate 101 occurring by moving the stage 105 to each height position. Then, the rotation variation amount Δθ1 and the magnification variation amount ΔM1 of the image of the multiple primary electron beams 20 on the surface of the substrate 101 occurring by correcting the shift amount of the focus position are measured at the shift amount ΔZ1 of each focus position.

Next, in a state where the shift amount ΔZ1 of the focus position and the magnification variation amount ΔM1 and the rotation variation amount Δθ1 on the surface of the substrate 101 are corrected by the three electrostatic lenses 230, 232, and 234 in the primary electron optics, the focus position variation amount ΔZ2, the magnification variation amount ΔM2, and the rotation variation amount Δθ2 of the multiple secondary electron beams 300 on the detection surface of the multiple detector 222 are measured.

Then, a correlation table is generated in which the rotation variation amount Δθ1 and the magnification variation amount ΔM1 of the image are defined depending on the shift amount ΔZ1 of the focus position. Simultaneously, in the correlation table, the focus position variation amount ΔZ2, the magnification variation amount ΔM2, and the rotation variation amount Δθ2 on the detection surface of the multiple detector 222 in the state where the shift amount ΔZ1 of the focus position, the magnification variation amount ΔM1, and the rotation variation amount Δθ1 on the surface of the substrate 101 are corrected by the three electrostatic lenses 230, 232, and 234 in the primary electron optics are defined in association with the shift amount ΔZ1 of the focus position on the surface of the substrate 101.

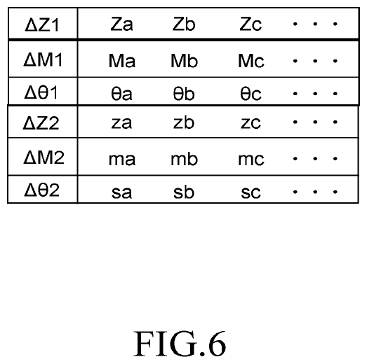

FIG. 6 is a diagram illustrating an example of the correlation table in Embodiment 1. In FIG. 6, in the correlation table, in a case where the shift amount ΔZ1 of the focus position on the surface of the substrate 101 is changed to Za, Zb, Zc, . . . , the rotation variation amount Δθ1 and the magnification variation amount ΔM1 of the image on the surface of the substrate 101 occurring in a case where the shift amount ΔZ1 of each focus position is corrected by, for example, the electrostatic lens 234 are defined. In the example of FIG. 6, in a case where the shift amount ΔZ1 of the focus position on the surface of the substrate 101 is Za, it is illustrated that, for example, the magnification variation amount ΔM1 and the rotation variation amount Δθ1 of the image on the surface of the substrate 101 occurring when the shift amount Za of the focus position is corrected by the electrostatic lens 234 are Ma and θa, respectively. Similarly, in a case where the shift amount ΔZ1 of the focus position on the surface of the substrate 101 is Zb, it is illustrated that, for example, the magnification variation amount ΔM1 and the rotation variation amount Δθ1 of the image on the surface of the substrate 101 occurring when the shift amount Zb of the focus position is corrected by the electrostatic lens 234 are Mb and θb, respectively. Similarly, in a case where the shift amount ΔZ1 of the focus position on the surface of the substrate 101 is Zc, it is illustrated that, for example, the magnification variation amount ΔM1 and the rotation variation amount Δ74 1 of the image on the surface of the substrate 101 occurring when the shift amount Zc of the focus position is corrected by the electrostatic lens 234 are Mc and θc, respectively.

Next, in the correlation table, in a case where the shift amount ΔZ1 of the focus position on the surface of the substrate 101 is changed to Za, Zb, Zc, the focus position variation amount ΔZ2, the magnification variation amount ΔM2, and the rotation variation amount Δθ2 on the detection surface of the multiple detector 222 in a state where the shift amount ΔZ1 of the focus position, the magnification variation amount ΔM1, and the rotation variation amount Δθ1 on the surface of the substrate 101 are corrected by the three electrostatic lenses 230, 232, and 234 in the primary electron optics are defined. In the example of FIG. 5, it is illustrated that, in a case where the shift amount ΔZ1 of the focus position on the surface of the substrate 101 is Za, the focus position variation amount ΔZ2 on the detection surface of the multiple detector 222 is za, the magnification variation amount ΔM2 of the image is ma, and the rotation variation amount Δθ2 is sa. Similarly, it is illustrated that, in a case where the shift amount ΔZ1 of the focus position on the surface of the substrate 101 is Zb, the focus position variation amount ΔZ2 on the detection surface of the multiple detector 222 is zb, the magnification variation amount ΔM2 of the image is mb, and the rotation variation amount Δθ2 is sb. Similarly, it is illustrated that, in a case where the shift amount ΔZ1 of the focus position on the surface of the substrate 101 is Zc, the focus position variation amount ΔZ2 on the detection surface of the multiple detector 222 is zc, the magnification variation amount ΔM2 of the image is mc, and the rotation variation amount Δθ2 is sc.

Alternatively, instead of the correlation table, a correlation expression may be used. For example, the magnification variation amount is approximated by ΔM1=k·ΔZ1, and the rotation variation amount is approximated by Δθ1=k′·ΔZ1. Similarly, the shift amount of the focus position is approximated by ΔZ2=K·ΔZ1, the magnification variation amount is approximated by ΔM2=K′·ΔZ1, and the rotation variation amount is approximated by Δθ2=K″·ΔZ1. The coefficients (parameters) k, k′, K, K′, and K″ of the approximation expression are obtained. Herein, as an example, although illustrated by a linear expression, embodiments are not limited thereto. The approximation may be performed by using a polynomial including second or higher order terms.

The parameters k, k′, K, K′, and K″ of the generated correlation table or the calculated approximation expression are stored in the storage device 111.

In the substrate height measurement step (S104), the height position of the substrate 101 to be inspected is measured by the Z sensor 217. The measurement result of the Z sensor 217 is output to the Z position measurement circuit 129. In addition, the information of each height position of the surface of the substrate 101 is stored in the storage device 109 together with the x and y coordinates of the measurement position on the surface of the substrate 101 measured by the position circuit 107. In addition, embodiments are not limited to a case where the height position of the substrate 101 is measured in advance before the image acquisition. The height position of the substrate 101 may be measured in real time while acquiring an image.

In the inspection target image acquisition step (S202), the image acquisition mechanism 150 acquires a secondary electron image of a pattern formed on the substrate 101 by using the multiple primary electron beams 20. Specifically, the operation is as follows.

First, the stage 105 on which the substrate 101 is mounted is moved in a state where the multiple beams 20 is focused on the reference position on the surface of the substrate 101 by the electromagnetic lens 207 (objective lens). If the stage 105 on which the substrate 101 is mounted is continuously moved, the image acquisition mechanism 150 irradiates the substrate 101 with the multiple primary electron beams 20 in a state where the focus position of the multiple primary electron beams 20 is aligned with the reference position on the surface of the substrate 101 by the electromagnetic lens 207 (objective lens). In addition, needless to say, the electromagnetic lenses 205, 206, and 207 are adjusted so that the multiple primary electron beams 20 are focused on the surface of the substrate 101. In addition, in such a case, needless to say, the respective electromagnetic lenses 224, 225, 226 are adjusted so that each beam of the multiple secondary electron beams 300 is detected on the desired light receiving surface of the multiple detector 222.

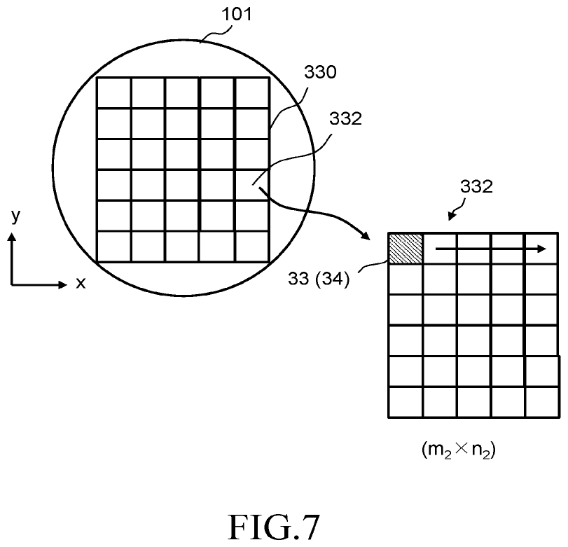

FIG. 7 is a diagram illustrating an example of a plurality of chip regions formed on the semiconductor substrate in Embodiment 1. In FIG. 7, in a case where the substrate 101 is the semiconductor substrate (wafer), a plurality of chips (wafer dies) 332 are formed in a two-dimensional array shape in the inspection region 330 of the semiconductor substrate (wafer). A mask pattern for one chip formed on the mask substrate for exposure is reduced to, for example, ¼ and transferred to each chip 332 by an exposure apparatus (stepper) (not illustrated). The inner portion of each chip 332 is divided into, for example, a plurality of two-dimensional width (x direction) m₂ columns×length (y direction) n₂ stages (m₂ and n, are integers of 2 or more) of mask dies 33. In Embodiment 1, the mask die 33 is a unit inspection region. The movement of the beam to the target mask die 33 is performed by collective deflection of the entire multiple beams 20 by the main deflector 208.

Before the irradiation of the multiple primary electron beams 20 to the target mask die 33, the variation amount calculation circuit 130 uses the x and y coordinates of the irradiation position of the multiple beams 20 to read out the height position of the substrate 101 stored in the storage device 109. A difference between the read height position and the reference position of the surface of the substrate 101 focused by the electromagnetic lens 207 (objective lens) is calculated. The difference corresponds to the shift amount ΔZ1 of the focus position from the reference position. Alternatively, it is preferable to store information on the height position of the substrate 101 in the storage device 109 as the difference from the reference position, that is, as the shift amount ΔZ1 of the focus position from the reference position.

Next, the variation amount calculation circuit 130 reads out the correlation table (or the parameters k, k′, K, K′, and K″ of the approximation expression) stored in the storage device 111 and calculates the rotation variation amount Δθ1 and the magnification variation amount ΔM1 according to the shift amount ΔZ1 of the focus position from the reference position caused by the variation of the height position of the surface of the substrate 101 occurring according to the movement of the stage 105 by using the correlation table (or the approximation expression). In addition, by using the correlation table (or the approximation expression), the variation amount calculation circuit 130 calculates the focus position variation amount ΔZ2, the magnification variation amount ΔM2, and the rotation variation amount Δθ2 on the detection surface of the multiple detector 222 in the state where the shift amount ΔZ1 of the focus position on the surface of the substrate 101, the magnification variation amount ΔM1, and rotation variation amount Δθ1 are corrected by the three electrostatic lenses 230, 232, and 234 in the primary electron optics according to the shift amount ΔZ1 of the focus position from the reference position. Each information of the shift amount ΔZ1 of the focus position and the calculated rotation variation amount Δθ1, magnification variation amount ΔM1, focus position variation amount ΔZ2, magnification variation amount ΔM2, and rotation variation amount Δθ2 is output to the electrostatic lens control circuit 121. It is preferable that the calculation of the shift amount ΔZ1 of the focus position, the rotation variation amount Δθ1 according to the shift amount ΔZ1 of the focus position, the magnification variation amount ΔM1, the focus position variation amount ΔZ2, the magnification variation amount ΔM2, and the rotation variation amount 402 is performed for each mask die 33 which is the unit inspection region. Alternatively, the calculation may be performed for each movement distance of the stage 105 which is shorter than the size of the mask die 33. Alternatively, the calculation may be performed for each movement distance of the stage 105 which is longer than the size of the mask die 33.

The electrostatic lens control circuit 121 calculates a combination of a lens control value 1 of the electrostatic lens 230, a lens control value 2 of the electrostatic lens 232, and a lens control value 3 of the electrostatic lens 234 for correcting the shift amount ΔZ1 of the focus position, the rotation variation amount Δθ1, and the magnification variation amount ΔM1. In addition, the electrostatic lens control circuit 121 calculates a combination of a lens control value 4 of the electrostatic lens 231, a lens control value 5 of the electrostatic lens 233, and a lens control value 6 of the electrostatic lens 235 for correcting the shift amount ΔZ2 of the focus position, the rotation variation amount 402, and the magnification variation amount ΔM2. The combination of the lens control values 1, 2, and 3 for correcting the shift amount ΔZ1 of the focus position, the rotation variation amount Δθ1, and the magnification variation amount ΔM1 and the combination of the lens control values 4, 5, and 6 for correcting the shift amount ΔZ2 of the focus position, the rotation variation amount 402, and the magnification variation amount ΔM2 may be obtained in advance by experiments or the like.

Then, in synchronization with the movement of the stage 105, in other words, the variation of the height position of the substrate 101 at the irradiation position of the multiple primary electron beams 20, the electrostatic lens control circuit 121 applies a potential corresponding to the calculated lens control value 1 to the control electrode (middle electrode substrate) of the electrostatic lens 230, applies a potential corresponding to the calculated lens control value 2 to the control electrode (middle electrode substrate) of the electrostatic lens 232, and applies a potential corresponding to the calculated lens control value 3 to the control electrode (middle electrode substrate) of the electrostatic lens 234. In addition, in synchronization with the movement of the stage 105 in the same manner, the electrostatic lens control circuit 121 applies a potential corresponding to the calculated lens control value 4 to the control electrode (middle electrode substrate of the electrostatic lens 231) applies a potential corresponding to the lens control value 5 to the control electrode (middle electrode substrate) of the electrostatic lens 233, and applies a potential corresponding to the calculated lens control value 6 to the control electrode (middle electrode substrate) of the electrostatic lens 235.

As a result, the electrostatic lenses 230, 232, and 234 of the electrostatic lens group in the primary optics dynamically correct the shift amount ΔZ1 of the focus position of the multiple primary electron beams from the reference position on the surface of the substrate 101 occurring according to the movement of stage 105 and the rotation variation amount Δθ1 and the magnification variation amount ΔM1 of the multiple primary electron beams 20 on the surface of the substrate 101 occurring by correcting the shift amount ΔZ1 of the focus position of the multiple primary electron beams 20. In this manner, the electrostatic lenses 230, 232, and 234 dynamically correct the shift amount ΔZ1 of the focus position and the rotation variation amount Δθ1 and the magnification variation amount ΔM1 obtained by using the correlation table (or the approximation expression). In the example of FIG. 1, a case where the electrostatic lens group in the primary optics is configured with the three electrostatic lenses 230, 232, 234 is illustrated, but embodiments are not limited thereto. The electrostatic lens group in the primary optics maybe configured with three or more electrostatic lenses.

In addition, simultaneously, the electrostatic lenses 231, 233, and 235 of the electrostatic lens group in the secondary optics dynamically correct the focus position variation amount ΔZ2 of the multiple secondary electron beams 300 which are emitted from the substrate 101 by irradiating the substrate 101 with the multiple primary electron beams 20 corrected by the electrostatic lenses 230, 232, and 234 and pass through the electrostatic lens 234 and the rotation variation amount Δθ2 and the magnification variation amount ΔM2 of the image of the multiple secondary electron beams 300. As described above, the electrostatic lenses 231, 233, and 235 dynamically correct the focus position variation amount ΔZ2, the rotation variation amount Δθ2, and the magnification variation amount ΔM2 by using a correlation table (or an approximation expression). In the example of FIG. 1, a case where the electrostatic lens group of the secondary optics is configured with the three electrostatic lenses 231, 233, and 235 is illustrated, but embodiments are not limited thereto. In the image acquisition of a fine pattern on the substrate 101, the secondary optics is magnifying optics. Therefore, the depth of focus becomes deep. For this reason, even if the focus position variation amount ΔZ2 of the multiple secondary electron beams 300 occurs, the influence on the obtained secondary electron image can be reduced. For this reason, the correction for the multiple secondary electron beams 300 may be performed on the rotation variation amount Δθ2 and the magnification variation amount ΔM2 of the remaining image while the correction of the focus position variation amount ΔZ2 is omitted. Therefore, since the number of variation parameters is two, the electrostatic lens group in the secondary optics may be configured with two or more electrostatic lenses.

In addition, in the example of FIG. 1, a case where the multiple secondary electron beams 300 pass through the electrostatic lens 234 of the electrostatic lens group in the primary optics has been described, but embodiments are not limited thereto. In some cases, depending on the arranged position of the beam separator 214, the multiple secondary electron beams 300 may pass through another electrostatic lens, for example, the electrostatic lens 232. In that case, it is needless to say that the trajectory of the multiple secondary electron beams 300 is further influenced by the electrostatic lens 234 and the other electrostatic lenses described above. As described above, the electrostatic lenses 231, 233, and 235 correct the focus position variation, the magnification variation, and the rotation variation of the multiple secondary electron beams 300 passing through at least one electrostatic lens of the electrostatic lens group in the primary optics. In addition, the electrostatic lenses 231, 233, and 235 are arranged at the positions (secondary optics) where the multiple primary electron beams 20 do not pass so as not to influence the trajectory of the multiple primary electron beams 20.

In addition, in the example of FIG. 1, a case where the three electromagnetic lenses 224, 225, and 226 for refracting the multiple secondary electron beams 300 are arranged in the secondary optics is illustrated, but embodiments are not limited thereto. The multiple secondary electron beams 300 may be guided to the multiple detector 222, and at least one electromagnetic lens may be arranged in the secondary optics. For example, one electromagnetic lens may be arranged. Or two electromagnetic lenses may be arranged. Or three or more electromagnetic lenses may be arranged. In addition, in the example of FIG. 1, each electrostatic lens of the electrostatic lens group in the secondary optics is arranged in the magnetic field of a different electromagnetic lens. In such a case, as described above, in a case where the electrostatic lens group in the secondary optics is configured with two or more electrostatic lenses in order to perform the correction of the rotation variation amount 402 and the magnification variation amount ΔM2, two electromagnetic lenses may be arranged. However, embodiments are not limited thereto.

Among the electrostatic lenses 231, 233, and 235, the electrostatic lens that contributes to at least the correction of the rotation variation amount Δθ2 may be arranged in the magnetic field of the electromagnetic lens. In other words, at least one electrostatic lens of the electrostatic lens group in the secondary optics may be arranged in the magnetic field of at least one electromagnetic lens arranged in the secondary optics.

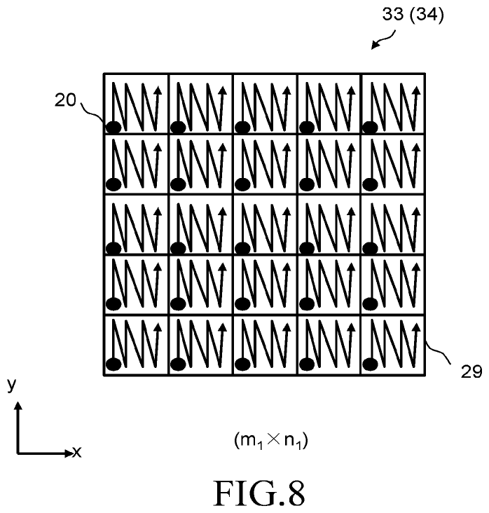

FIG. 8 is a diagram illustrating a multiple beam scan operation in Embodiment 1. In the example of FIG. 8, the case of 5×5 multiple primary electron beams 20 is illustrated. The irradiation region 34 which can be irradiated by the irradiation of one multiple primary electron beams 20 is defined by (the size in the x direction obtained by multiplying the inter-beam pitch in the x direction of the multiple primary electron beams 20 on the surface of the substrate 101 by the number of beams in the x direction)×(the size in the y direction obtained by multiplying the inter-beam pitch in the y direction of the multiple primary electron beams 20 on the surface of the substrate 101 by the number of beams in the y direction). In the example of FIG. 8, a case where the irradiation region 34 has the same size as the mask die 33 is illustrated. However, embodiments are not limited thereto. The irradiation region 34 may be smaller than the mask die 33. Alternatively, the irradiation region 34 may be large than the mask die 33. Then, the inside of the sub-irradiation region 29 surrounded by the inter-beam pitch in the x direction and the inter-beam pitch in the y direction where the beam is located is scanned with each beam of the multiple primary electron beams 20. Each beam constituting the multiple primary electron beams 20 is allocated to any of different sub-irradiation regions 29. Then, at each shot, the same position in the assigned sub-irradiation region 29 is irradiated with each beam. The movement of the beam in the sub-irradiation region 29 is performed by collective deflection of the entire multiple primary electron beams 20 by the sub deflector 209. The operations are repeated, and all the positions in one sub-irradiation region 29 are sequentially irradiated with one beam.

Due to the fact that the desired position of the substrate 101 is irradiated with the multiple primary electron beams 20 corrected by the electrostatic lenses 230, 232, and 234, the multiple secondary electron beams 300 including reflected electrons are emitted corresponding to the multiple primary electron beams 20 from the substrate 101. The multiple secondary electron beams 300 emitted from the substrate 101 travel to the beam separator 214 and are bent obliquely upward. The multiple secondary electron beams 300 bent obliquely upward are bent in the trajectory by the deflector 218 and projected onto the multiple detector 222. In this manner, the multiple detector 222 detects the multiple secondary electron beams 300 including the reflected electrons emitted due to the fact that the surface of the substrate 101 is irradiated with the multiple primary electron beams 20.

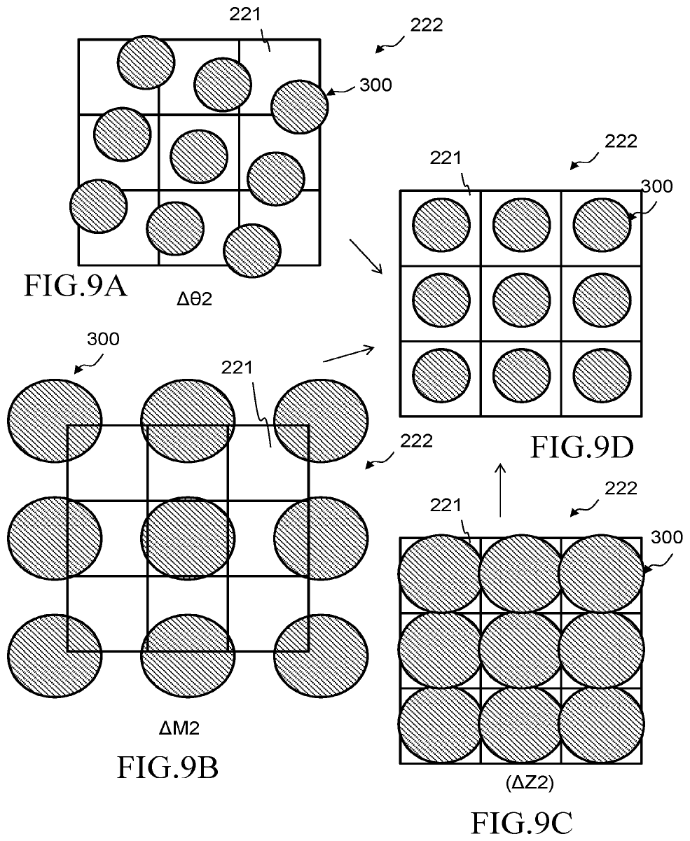

FIGS. 9A to 9D are diagrams illustrating a variation of the multiple secondary electron beams on the detection surface of the detector and the corrected state in Embodiment 1. In a case where the rotation variation amount Δθ2 of the image of the multiple secondary electron beams 300 occurs, as illustrated in FIG. 9A, each beam of the multiple secondary electron beams 300 is shifted from the detection surface 221 to be detected by the multiple detector 222 and is projected. For this reason, a shift occurs in the obtained image. By correcting the rotation variation amount Δθ2 of the image, each beam can be allowed to fall within the detection surface 221 to be detected by the multiple detector 222 as illustrated in FIG. 9D. In a case where the magnification variation amount ΔM2 of the image of the multiple secondary electron beams 300 occurs, as illustrated in FIG. 9B, each beam of the multiple secondary electron beams 300 is shifted from the detection surface 221 to be detected by the multiple detector 222 and is projected. For example, if the image is enlarged, it is difficult to receive light on the detection surface 221 to be detected only by moving the projection position. By correcting the magnification variation amount ΔM2 of the image, each beam can be allowed to fall within the detection surface 221 to be detected by the multiple detector 222 as illustrated in FIG. 9D. In addition, as described above, in a case where the size of each beam becomes larger than the detection surface 221 to be detected as illustrated in FIG. 9C due to the focus position variation amount ΔZ2 of the multiple secondary electron beams 300, the correct of the focus position variation amount ΔZ2 is needed. The correction of the focus position variation amount ΔZ2 allows each beam to fall within the detection surface 221 to be detected by the multiple detector 222 as illustrated in FIG. 9D.

In this manner, the mask die 33 as the irradiation region 34 is scanned with the entire multiple primary electron beams 20, but the corresponding one sub-irradiation region 29 can be scanned with each beam. Then, when the scanning of one mask die 33 is completed, the adjacent next mask die 33 is moved to be the irradiation region 34, and the scanning of the adjacent next mask die 33 is performed. In conjunction with the operation, the electrostatic lenses 230, 232, and 234 in the primary optics dynamically correct the shift amount ΔZ1 of the focus position of the multiple primary electron beams 20 from the reference position and the rotation variation amount Δθ1 and the magnification variation amount ΔM1 of the image of the multiple beams 20 on the substrate 101 according to the shift amount ΔZ1 of the focus position. Similarly, in conjunction with this operation, the electrostatic lenses 231, 233, and 235 in the secondary optics dynamically correct the focus position variation amount ΔZ2 of the multiple secondary electron beams 300 and the rotation variation amount Δθ2 and the magnification variation amount ΔM2 of the image of the multiple secondary electron beams 300. The operations are repeated to perform the scanning of each chip 332. By each shot of the multiple primary electron beams 20, secondary electrons emit from the irradiated position each time, and the multiple secondary electron beams 300 corrected by the electrostatic lenses 231, 233, and 235 in the secondary optics is detected by the multiple detector 222.

In this manner, in the case of scanning with the multiple primary electron beams 20, the scanning operation (measurement) can be performed at higher speed than in the case of scanning with a single beam. In a case where the irradiation region 34 is smaller than the mask die 33, the scanning operation may be performed while the irradiation region 34 is allowed to be moved within the mask die 33.

In a case where the substrate 101 is a mask substrate for exposure, a chip region for one chip formed on the mask substrate for exposure is divided into a plurality of stripe regions in a strip shape, for example, with the size of the mask die 33 described above. Then, for each stripe region, each mask die 33 may be scanned by the same scan operation as the operation described above. The size of the mask die 33 in the mask substrate for exposure is the size before transfer, and thus, the size of the mask die 33 in the mask substrate for exposure is four times the size of the mask die 33 in the semiconductor substrate. For this reason, in a case where the irradiation region 34 is smaller than the mask die 33 in the mask substrate for exposure, the number of times of the scanning operation for one chip is increased (for example, four times). However, since a pattern for one chip is formed on the mask substrate for exposure, the number of times of the scanning can be reduced in comparison to a semiconductor substrate on which more than four chips are formed.

As described above, the image acquisition mechanism 150 scans the inspection target substrate 101 on which the figure is formed by using the multiple primary electron beams 20 and detects the multiple secondary electron beams 300 emitted from the inspection target substrate 101 caused by irradiation of the multiple primary electron beams 20. The detection data (the measurement image, the secondary electron image, and the inspection target image) of the secondary electrons from each of the measurement pixels 36 detected by the multiple detector 222 is output to the detection circuit 106 in the order of measurement. In the detection circuit 106, analog detection data is converted into digital data by an A/D converter (not illustrated) and stored in the chip pattern memory 123. Thus, the image acquisition mechanism 150 acquires the measurement image of the pattern formed on the substrate 101. Then, for example, in the step where the detection data for the one chip 332 is accumulated, the detection data together with information indicating each position from the position circuit 107 as chip pattern data is transmitted to the comparison circuit 108.

In the reference image generation step (S205), the reference image generation circuit 112 (reference image generation unit) generates a reference image corresponding to the inspection target image. The reference image generation circuit 112 generates a reference image for each frame area on the basis of a design data based on which the pattern is formed on the substrate 101 or a design pattern data defined in an exposure image data of the pattern formed on the substrate 101. For example, it is preferable to use the mask die 33 as the frame region. Specifically, the operations are as follows. First, the design pattern data is read out from the storage device 109 through the control calculator 110, and each figure defined in the read-out design pattern data is converted into binary or multi-valued image data.

Herein, the figure defined in the design pattern data is, a figure having, for example, a rectangle or triangle as a basic figure, and for example, figure data in which the shape, size, position, and the like of each pattern figure are defined is stored as information such as the coordinates (x, y) at the reference position, the length of the side, and a figure code serving as an identifier for distinguishing a figure type such as a rectangle or a triangle of the figure.

If the design pattern data to be the figure data is input to the reference image generation circuit 112, the design pattern data is developed to the data for each figure, and thus, the figure code indicating the figure shape, the figure dimensions, and the like in the figure data are interpreted. Then, the data is developed as the binary or multi-valued design pattern image data as a pattern arranged in squares in units of grid having a predetermined quantization dimension and is output. In other words, the design data is read out, and the occupancy rate of the figure in the design pattern is calculated for each square obtained by virtually dividing the inspection region into squares in units of predetermined dimensions, and the n-bit occupancy rate data is output. For example, it is preferable to set one square as one pixel. Then, it is assumed that a resolution of ½⁸ (= 1/256) is given to one pixel, a small area of 1/256 is allocated to the region of the figure arranged in the pixel, and the occupancy rate in the pixel is calculated. Then, the 8-bit occupancy rate data is output to the reference image generation circuit 112. The squares (inspection pixels) maybe aligned with the pixels of the measurement data.

Next, the reference image generation circuit 112 performs appropriate filtering on the design image data of the design pattern which is the image data of the figure. Since an optical image data as a measurement image is in a state where filtering is applied by optics, in other words, in a continuously changing analog state, the filter processing is also applied on a design image data which is an image data on the design side, of which image intensity (gray scale value) is a digital value, so that the measured data can be aligned. The image data of the generated reference image is output to the comparison circuit 108.

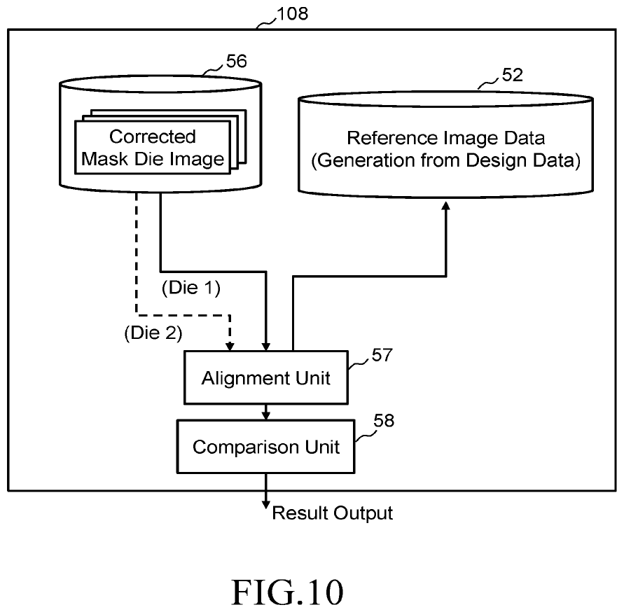

FIG. 10 is a configuration diagram illustrating an example of a configuration in the comparison circuit in Embodiment 1. In FIG. 10, in the comparison circuit 108, storage devices 52 and 56 such as magnetic disk drives, an alignment unit 57, and a comparison unit 58 are arranged. Each “˜unit” such as the alignment unit 57 and the comparison unit 58 includes a processing circuit, and the processing circuit includes an electric circuit, a computer, a processor, a circuit board, a quantum circuit, a semiconductor device, or the like. In addition, as each “˜circuit”, a common processing circuit (the same processing circuit) may be used. Alternatively, different processing circuits (separate processing circuits) maybe used. The input data or the calculation results required in the alignment unit 57 and the comparison unit 58 are stored in a memory (not illustrated) or a memory 118 each time.

In the comparison circuit 108, the transmitted pattern image data (secondary electron image data) is temporarily stored in the storage device 56. In addition, the transmitted reference image data is temporarily stored in the storage device 52.

In the alignment step (S206), the alignment unit 57 reads out a mask die image which is an inspection target image and a reference image corresponding to the mask die image and aligns both images in units of a sub pixel smaller than the pixel 36. The alignment may be performed by, for example, a least square method.

In the comparison step (S208), the comparison unit 58 compares the mask die image (inspection target image) with the reference image. The comparison unit 58 compares the two images for each pixel 36 according to a predetermined determination condition and determines whether or not a defect, for example, a shape defect exists. For example, if the difference in gray scale level for each pixel 36 is larger than a determination threshold Th, it is determined as a defect.

Then, the comparison result is output. The comparison result may be output to the storage device 109, the monitor 117, or the memory 118 or may be output from the printer 119.

In addition, not limited to the above-described die-database inspection, die-die inspection may be performed.

In a case where the die-die inspection is performed, the images of the mask die 33 on which the same pattern is formed may be compared with each other. Therefore, a mask die image of a partial region of the wafer die 332 which becomes the die (1) and a mask die image of the corresponding region of another wafer die 332 which becomes the die (2) are used. Alternatively, by using the mask die image of a partial region of the same wafer die 332 as the mask die image of the die (1) and using the mask die image of another partial region of the same wafer die 332 on which the same pattern is formed as the mask die image of the die (2), the comparison may be performed. In such a case, if one of the images of the mask die 33 on which the same pattern is formed is used as a reference image, the inspection can be performed in the same manner as the above-described die-database inspection.

That is, in the alignment step (S206), the alignment unit 57 reads out the mask die image of the die (1) and the mask die image of the die (2) and aligns the two images in units of a sub pixel smaller than the pixel 36. The alignment may be performed by, for example, a least square method.

Then, in the comparison step (S208), the comparison unit 58 compares the mask die image of the die (1) with the mask die image of the die (2). The comparison unit 58 compares the two images for each pixel 36 according to a predetermined determination condition and determines whether or not a defect, for example, a shape defect exists. For example, if the difference in gray scale level for each pixel 36 is larger than a determination threshold Th, it is determined as a defect. Then, the comparison result is output. The comparison result may be output to a storage device, a monitor, or a memory (not illustrated) or may be output from a printer.

As described above, according to Embodiment 1, three variation factors of the shift amount ΔZ1 of the focus position of the multiple primary electron beams 20 on the substrate 101 occurring according to the continuous movement on the stage 105 and the magnification variation amount ΔM1 and the rotation variation amount Δθ1 of the image caused by this shift amount are corrected by three or more electrostatic lenses. Furthermore, at least the magnification variation amount ΔM2 and the rotation variation amount 402 of the image on the detection surface of the multiple secondary electron beams 300 occurring by the correction are corrected by two or more electrostatic lenses. Therefore, the secondary electrons can be detected with high accuracy in an apparatus for acquiring an image by focusing a multiple beam on the continuously moving substrate 101.

In the above description, a series of “circuits” includes a processing circuit, and the processing circuit includes an electric circuit, a computer, a processor, a circuit board, a quantum circuit, a semiconductor device, or the like. In addition, as each “˜circuit”, a common processing circuit (the same processing circuit) may be used. Alternatively, different processing circuits (separate processing circuits) may be used. The program for executing the processor or the like may be recorded on a recording medium such as a magnetic disk drive, a magnetic tape device, an FD, or a read only memory (ROM). For example, the position circuit 107, the comparison circuit 108, the reference image generation circuit 112, the stage control circuit 114, the electrostatic lens control circuit 121, the lens control circuit 124, the blanking control circuit 126, the deflection control circuit 128, the Z position measurement circuit 129, the variation amount calculation circuit 130, and the image processing circuit 132 may be configured with at least one processing circuit described above.

Heretofore, the embodiments have been described with reference to specific examples. However, embodiments are not limited to these specific examples. Although the example of FIG. 1 illustrates a case where the multiple primary electron beams 20 is formed by the shaping aperture array substrate 203 from one beam irradiated from the electron gun assembly 201 serving as one irradiation source, embodiments are not limited thereto. In some modes, the multiple primary electron beams 20 may be formed by irradiation of primary electron beams from a plurality of irradiation sources.

In addition, although the apparatus configurations, control methods, components, and the like that are not directly necessary for the description of embodiments are omitted in description, the apparatus configurations and control methods can be appropriately selected and used if needed.

In addition, all multiple electron beam image acquisition apparatuses, multiple electron beam image acquisition methods, and multiple electron beam inspection apparatuses which include elements of embodiments and of which design can be modified appropriately by those skilled in the art are included in the scope of embodiments.

Additional advantages and modification will readily occur to those skilled in the art. Therefore, the invention in its broader aspects is not limited to the specific details and representative embodiments shown and described herein. Accordingly, various modifications maybe made without departing from the spirit or scope of the general inventive concept as defined by the appended claims and their equivalents.

What is claimed is:

1. An electron beam image acquisition apparatus comprising:
a stage on which a substrate to be irradiated with a primary electron beam being capable to be placed;
an objective lens focusing the primary electron beam on a reference position of a surface of the substrate;
a first electrostatic lens group including a plurality of electrostatic lenses, one electrostatic lens of the first electrostatic lens group being arranged in a magnetic field of the objective lens, the first electrostatic lens group correcting a shift amount of a focus position of the primary electron beam from the reference position on the surface of the substrate according to movement of the stage, and a plurality of variation amounts of the primary electron beam on the surface of the substrate by correcting the shift amount of the focus position of the primary electron beam;
a second electrostatic lens group, arranged at a position with the primary electron beam not passing through the position and including a plurality of electrostatic lenses, correcting a plurality of variation amounts of an image of a secondary electron beam being emitted from the substrate by irradiating the substrate with the primary electron beam corrected by the first electrostatic lens group, the secondary electron beam passing through at least one electrostatic lens of the first electrostatic lens group; and
a detector detecting the secondary electron beam corrected by the second electrostatic lens group.

2. The apparatus according to claim 1, further comprising:
a storage device storing a table or parameters of an approximation expression with a rotation variation amount and a magnification variation amount of the image of the secondary electron beam on a detection surface of the detector being defined depending on the shift amount of the focus position from the reference position of the surface of the substrate, the rotation variation amount and the magnification variation amount of the image of the secondary electron beam on the detection surface of the detector by correcting the shift amount of the focus position of the primary electron beam from the reference position caused by the variation of the height position of the surface of the substrate and a rotation variation amount and a magnification variation amount of the image of the primary electron beam on the surface of the substrate by correcting the shift amount of the focus position of the primary electron beam by the first electrostatic lens group.

3. The apparatus according to claim 2, wherein the second electrostatic lens group dynamically corrects the rotation variation amount and the magnification variation amount of the secondary electron beam according to the shift amount of the focus position of the primary electron beam by the table or the approximation expression.

4. The apparatus according to claim 1,
wherein three electrostatic lenses are used as the second electrostatic lens group, and
wherein the three electrostatic lenses of the second electrostatic lens group dynamically correct a rotation variation amount, a magnification variation amount, and a shift amount of the focus position of the secondary electron beam on the detection surface of the detector according to the shift amount of the focus position of the primary electron beam.

5. The apparatus according to claim 1, further comprising:
at least one electromagnetic lens refracting the secondary electron beam,
wherein at least one electrostatic lens of the second electrostatic lens group is arranged in a magnetic field of the at least one electromagnetic lens.

6. The apparatus according to claim 5,
wherein two or more electromagnetic lenses are used as the at least one electromagnetic lens, and
wherein each electrostatic lens of the second electrostatic lens group is arranged in a magnetic field of a different one of the two or more electromagnetic lenses.

7. The apparatus according to claim 1, further comprising:
at least one electromagnetic lens refracting the primary electron beam,
wherein at least one electrostatic lens of the first electrostatic lens group is arranged in a magnetic field of the at least one electromagnetic lens.

8. The apparatus according to claim 7,
wherein the first electrostatic lens group is formed with three or more electrostatic lenses
two or more electromagnetic lenses are used as the at least one electromagnetic lens, and
one electrostatic lens of the first electrostatic lens group is arranged in the magnetic field of the objective lens, and each electrostatic lens of the remaining two or more electrostatic lenses of the first electrostatic lens group is arranged in a magnetic field of a different one of the two or more electromagnetic lenses.

9. The apparatus according to claim 1, wherein the plurality of electrostatic lenses in the first electrostatic lens group include an electrostatic lens arranged at a position with the secondary electron beam not passing through the position and an electrostatic lens arranged at another position with the secondary electron beam passing through the another position.

10. The apparatus according to claim 2, further comprising:
a variation amount calculation circuit reading out the correlation table stored in the storage device and calculating the magnification variation amount and the rotation variation amount on the detection surface of the detector according to the shift amount of the focus position of the primary electron beam by the correlation table, in a state of the shift amount of the focus position, the magnification variation amount, and the rotation variation amount on the surface of the substrate being corrected by the first electrostatic lens group.

11. An electron beam image acquisition method comprising:
irradiating a substrate with a primary electron beam while moving a stage with the substrate being mounted, in a state of a focus position of the primary electron beam being aligned with a reference position of a surface of the substrate by an objective lens;
correcting a shift amount of the focus position of the primary electron beam from the reference position of the surface of the substrate occurring according to movement of the stage and a variation amount of the primary electron beam on the surface of the substrate by correcting the shift amount of the focus position of the primary electron beam by a first electrostatic lens group, one electrostatic lens of the first electrostatic lens group being arranged in a magnetic field of the objective lens;
correcting a variation amount of an image of a secondary electron beam being emitted from the substrate caused by irradiating the substrate with a primary electron beam corrected by the first electrostatic lens group, the secondary electron beam passing through at least one electrostatic lens of the first electrostatic lens group, by a second electrostatic lens group arranged at a position with the primary electron beam not passing through the position and configured with a plurality of electrostatic lenses; and
detecting the secondary electron beam corrected by the second electrostatic lens group and acquiring a secondary electron image on the basis of a signal of the detected secondary electron beam.

12. The method according to claim 11, further comprising:
storing, in a storage device, a table or parameters of an approximation expression with a rotation variation amount and a magnification variation amount of the image of the secondary electron beam on a detection surface of the detector being defined depending on the shift amount of the focus position from the reference position of the surface of the substrate, wherein
the rotation variation amount and the magnification variation amount of the image of the secondary electron beam on the detection surface of the detector occur by correcting the shift amount of the focus position of the primary electron beam from the reference position, a rotation variation amount and a magnification variation amount of the image of the primary electron beam on the surface of the substrate by correcting the shift amount of the focus position of the primary electron beam by the first electrostatic lens group, and
the shift amount of the focus position is caused by the variation of the height position of the surface of the substrate.

13. The method according to claim 12, wherein the second electrostatic lens group dynamically corrects the rotation variation amount and the magnification variation amount of the secondary electron beam according to the shift amount of the focus position of the primary electron beam by using the table or the approximation expression.

14. The method according to claim 12, further comprising:
reading out the correlation table stored in the storage device and calculating the magnification variation amount and the rotation variation amount on the detection surface of the detector according to the shift amount of the focus position of the primary electron beam by the correlation table, in a state of the shift amount of the focus position, the magnification variation amount, and the rotation variation amount on the surface of the substrate being corrected by the first electrostatic lens group.
